(19) United States
(12) Patent Application Publication
(10) Pub. No.: US 2015/0249193 A1
(43) Pub. Date: Sep. 3, 2015

(54) LIGHT EMITTING DEVICE PACKAGE HAVING PHOSPHOR LAYER AND METHOD OF FABRICATING THE SAME

(71) Applicant: SAMSUNG ELECTRONICS CO., LTD., Suwon-si (KR)

(72) Inventors: Sung-Yong HONG, Incheon (KR); Kyung Tae KIM, Hwaseong-si (KR); Hyung-Jin PARK, Yongin-si (KR); Hee-Seok PARK, Suwon-si (KR); Ji-Seok WANG, Suwon-si (KR)

(21) Appl. No.: 14/548,255

(22) Filed: Nov. 19, 2014

(30) Foreign Application Priority Data
Mar. 3, 2014 (KR) 10-2014-0025151

(51) Int. Cl. H01L 33/50; H01L 33/36; H01L 33/48

(52) U.S. Cl. CPC H01L 33/505; H01L 33/486; H01L 33/36

(57) ABSTRACT

Provided are light emitting device package having a phosphor layer and a method of fabricating the same. A package substrate having a wiring pattern is disposed. A light emitting device mounted on the package substrate is disposed. The light emitting device has a main body having a light emitting layer therein. The light emitting device has an upper electrode on an upper surface of the main body. A bonding wire is connected to the upper electrode and the wiring pattern. A phosphor layer is formed on the light emitting device. The phosphor layer has a recessed space to accommodate the upper electrode and the bonding wire. The phosphor layer covers a side surface of the light emitting device.

### CROSS-REFERENCE TO RELATED APPLICATION

This application claims priority under 35 U.S.C. §119 to Korean Patent Application No. 10-2014-0025151 filed on Mar. 3, 2014, the disclosure of which is hereby incorporated by reference in its entirety.

### BACKGROUND

1. Field

Embodiments of the inventive concept relate to a light emitting device package having a phosphor layer and a method of fabricating the same.

2. Description of Related Art

Various studies for improving the quality of light through a phosphor layer capable of emitting by using some of light emitted from a light emitting device as an excitation source have been conducted.

### SUMMARY

Embodiments of the inventive concept provide a light emitting device package capable of implementing light having a high luminance efficiency and uniform color.

Other embodiments of the inventive concept provide a method of fabricating a light emitting device package capable of implementing light having a high luminance efficiency and uniform color.

The technical objectives of the inventive concept are not limited to the above disclosure; other objectives may become apparent to those of ordinary skill in the art based on the following descriptions.

In accordance with an aspect of the inventive concept, a light emitting device package is provided. A package substrate having a wiring pattern is disposed. A light emitting device mounted on the package substrate is disposed. The light emitting device has a main body having a light emitting layer therein. The light emitting device has an upper electrode on an upper surface of the main body. A bonding wire is connected to the upper electrode and the wiring pattern. A phosphor layer is formed on the light emitting device. The phosphor layer has a recessed space to accommodate the upper electrode and the bonding wire. The phosphor layer covers a side surface of the light emitting device.

In an embodiment, the phosphor layer may include a body formed to have a uniform thickness on a part of an upper surface of the light emitting device. The phosphor layer may include a side surface cap which is materially continuous with the body. The side surface cap may cover a side surface of the light emitting layer. The phosphor layer may include an upper cap which is materially continuous with the body. The upper cap may be formed to correspond to the upper electrode by being spaced apart by a height of the recessed space. The height of the recessed space may be smaller than the thickness of the body.

In another embodiment, a side surface of the body may protrude from the side surface of the light emitting device, or be in contact with the recessed space.

A side surface of the upper cap may protrude from the side surface of the light emitting device, or may contact the side surface of the body in contact with the recessed space.

In still another embodiment, the side surface cap may be formed from the upper surface of the main body to a lower surface of the light emitting layer.

In yet another embodiment, the side surface cap may be formed to expose the side surface of the light emitting device in contact with the recessed space.

In yet another embodiment, the recessed space may include at least a part of a bonding space corresponding to the upper electrode and the bonding wire.

In yet another embodiment, the height of the recessed space may be equal to or greater than a height of the bonding space.

In yet another embodiment, the light emitting device may have an etched space vertically and partially etched from the upper surface of the main body. The light emitting device may have the upper electrode on an upper surface exposed by the etched space.

In yet another embodiment, the recessed space may be vertically arranged with the etched space. The height of the recessed space may be equal to or greater than a difference between the height of the bonding space and a height of the etched space.

In yet another embodiment, the phosphor layer may include a body formed to have a uniform thickness on part of an upper surface of the light emitting device. The phosphor layer may include a side surface cap which is materially continuous with the body. The side surface cap may cover the side surface of the light emitting layer. The height of the recessed space may be the same as the thickness of the body.

In accordance with another aspect of the inventive concept, a light emitting device package is provided. A package substrate having first and second wiring patterns is disposed. A light emitting device mounted on the first wiring pattern is disposed. The light emitting device has an upper electrode. A bonding wire is connected to the upper electrode and the second wiring pattern. A phosphor layer is formed on the light emitting device. The phosphor layer has a recessed space to accommodate the upper electrode and the bonding wire.

In an embodiment, the phosphor layer may include a body formed to have a uniform thickness on a part of an upper surface of the light emitting device. The phosphor layer may include an upper cap which is materially continuous with the body. The upper cap may be formed to correspond to the upper electrode by being spaced apart by a height of the recessed space. The height of the recessed space may be smaller than the thickness of the body.

In another embodiment, a side surface of the body may be vertically arranged with a side surface of the light emitting device, or contact the recessed space.

In still another embodiment, a side surface of the upper cap may be vertically arranged with the side surface of the light emitting device, or may contact the side surface of the body in contact with the recessed space.

Details of other embodiments are included in detailed explanations and the drawings.

### BRIEF DESCRIPTION OF THE DRAWINGS

The foregoing and other features and advantages of the inventive concepts will be apparent from the more particular description of preferred embodiments of the inventive concepts, as illustrated in the accompanying drawings in which like reference characters refer to the same parts throughout the different views. The drawings are not necessarily to scale, emphasis instead being placed upon illustrating the principles of the inventive concepts. In the drawings:

FIG. 1A is a perspective view of a light emitting device package in accordance with an embodiment of the inventive concept, FIG. 1B is a cross-sectional view taken along line I-I′ of FIG. 1A, and FIG. 1C is a bottom perspective view of a phosphor layer shown in FIG. 1A;

FIG. 2A is a perspective view of a light emitting device package in accordance with another embodiment of the inventive concept, FIG. 2B is a cross-sectional view taken along line II-II′ of FIG. 2A, and FIG. 2C is a bottom perspective view of a phosphor layer shown in FIG. 2A;

FIG. 3A is a perspective view of a light emitting device package in accordance with still another embodiment of the inventive concept, and FIG. 3B is a cross-sectional view taken along line III-III′ of FIG. 3A;

FIG. 4A is a perspective view of a light emitting device package in accordance with yet another embodiment of the inventive concept, FIG. 4B is a cross-sectional view taken along line IV-IV′ of FIG. 4A, and FIG. 4C is a bottom perspective view of a phosphor layer shown in FIG. 4A;

FIG. 5A is a perspective view of a light emitting device package in accordance with yet another embodiment of the inventive concept, FIG. 5B is a cross-sectional view taken along line V-V′ of FIG. 5A, and FIG. 5C is a bottom perspective view of a phosphor layer shown in FIG. 5A;

FIG. 6A is a perspective view of a light emitting device package in accordance with yet another embodiment of the inventive concept, and FIG. 6B is a cross-sectional view taken along line VI-VI′ of FIG. 6A;

FIG. 7A is a perspective view of a light emitting device package in accordance with yet another embodiment of the inventive concept, FIG. 7B is a cross-sectional view taken along line VII-VII′ of FIG. 7A, and FIG. 7C is a bottom perspective view of a phosphor layer shown in FIG. 7A;

FIG. 8A is a perspective view of a light emitting device package in accordance with yet another embodiment of the inventive concept, and FIG. 8B is a cross-sectional view taken along line VIII-VIII′ of FIG. 8A;

FIGS. 9 to 18 are views showing a method of fabricating a light emitting device package in accordance with embodiments of the inventive concept;

FIG. 19 is a conceptual view illustrating a turn signal including at least one of the light emitting device packages in accordance with embodiments of the inventive concept; and

FIG. 20 is a schematic view illustrating a device assembly including at least one of the light emitting device packages in accordance with embodiments of the inventive concept.

### DETAILED DESCRIPTION OF THE EMBODIMENTS

The inventive concept will now be described more fully hereinafter with reference to the accompanying drawings, in which embodiments of the inventive concept are shown. This inventive concept may, however, be embodied in different forms and should not be construed as limited to the embodiments set forth herein. Rather, these embodiments are provided so that this disclosure is thorough and complete and fully conveys the scope of the inventive concept to one skilled in the art. The terminology used herein is for the purpose of describing particular embodiments only and is not intended to be limiting of the present inventive concept.

As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on,” “connected to,” or “coupled to” another element or layer, it can be directly on, connected, or coupled to the other element or layer or intervening elements or layers may be present. In contrast, when an element is referred to as being “directly on,” “directly connected to,” or “directly coupled to” another element or layer, there are no intervening elements or layers present. Like numerals refer to like elements throughout. As used herein, the term “and/or” includes any and all combinations of one or more of the associated listed items.

Spatially relative terms, such as “beneath,” “below,” “lower,” “above,” “upper,” and the like, may be used herein for ease of description in describing one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and to limit the scope of the present inventive concept.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

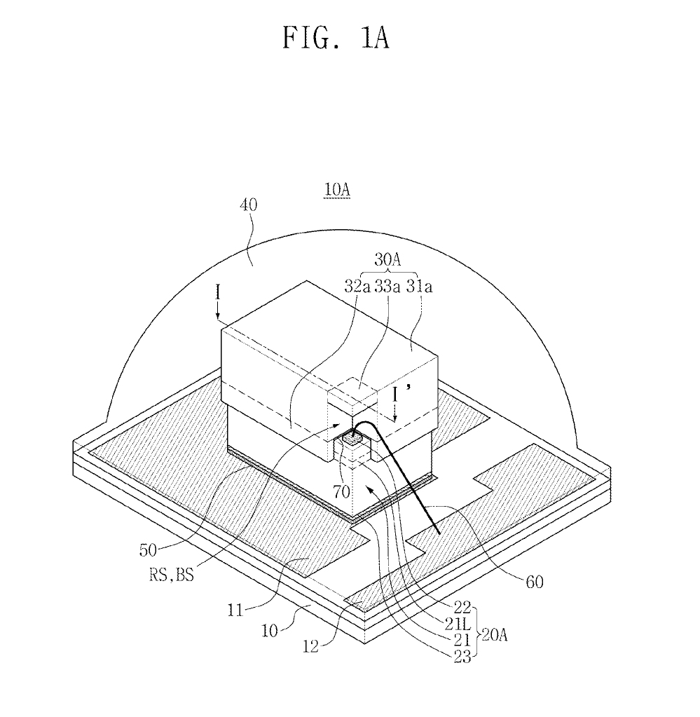

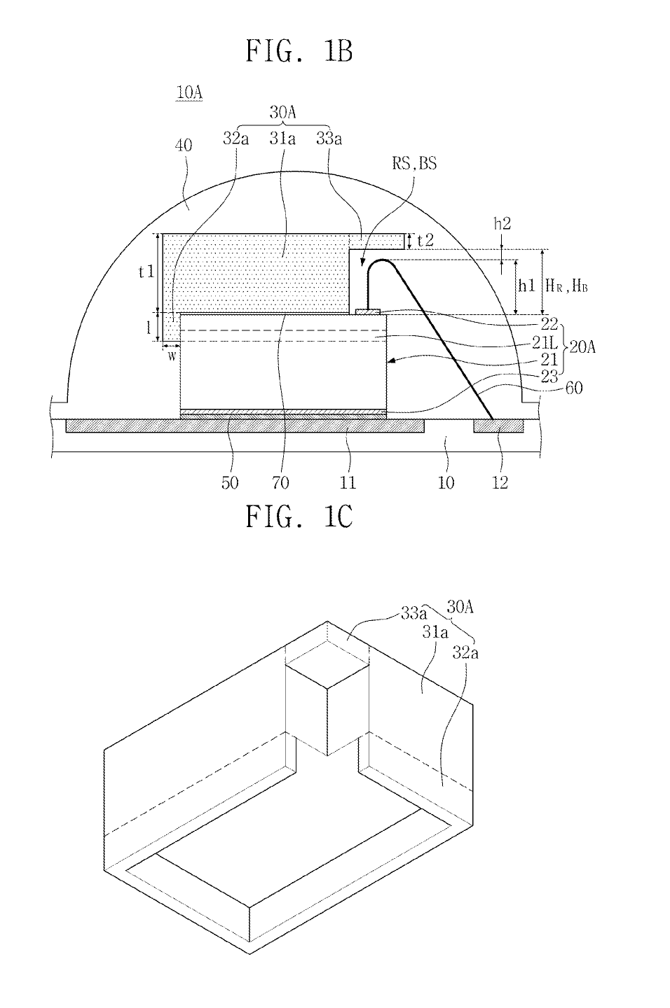

FIG. 1A is a perspective view of a light emitting device package in accordance with an embodiment of the inventive concept, FIG. 1B is a cross-sectional view taken along line I-I′ of FIG. 1A, and FIG. 1C is a bottom perspective view of a phosphor layer shown in FIG. 1A. Referring to FIGS. 1A to 1C, a light emitting device package 10A in accordance with an embodiment of the inventive concept may include a package substrate 10, a light emitting device 20A, and a phosphor layer 30A. The light emitting device package 10A in accordance with the embodiment of the inventive concept may further include a molding unit 40, a conductive adhesive member 50, a bonding wire 60, and an insulating adhesive member 70.

As the package substrate 10 is a substrate, which supports the light emitting device 20A mounted thereon, it may have wiring patterns 11 and 12 electrically connected to the light emitting device 20A. The wiring patterns 11 and 12 may be disposed to be electrically separated from each other in the package substrate 10. Surfaces of the wiring patterns 11 and 12 may have the same horizontal co-planar plane as a surface of the package substrate 10. The wiring patterns 11 and 12 may include a first wiring pattern 11 on which the light emitting device 20A is mounted, and a second wiring pattern 12 electrically separated from the first wiring pattern 11. The package substrate 10 may include a ceramic substrate. The wiring patterns 11 and 12 may include gilding.

The light emitting device 20A may be mounted on the package substrate 10. For example, the light emitting device 20A may be mounted on the first wiring pattern 11 of the package substrate 10. The light emitting device 20A may include a main body 21 having a light emitting layer 21L therein. The light emitting device 20A may include one or more upper electrodes 22 formed on an upper surface of the main body 21, and a lower electrode 23 formed on a lower surface of the main body 21. Although one upper electrode 22 is shown to make easier understanding of the embodiment of the inventive concept, the embodiment of the inventive concept is not limited thereto, and the plurality of upper electrodes 22 can be formed. The light emitting device 20A may include a blue light emitting diode (LED) to output blue-light.

The phosphor layer 30A may be formed on the light emitting device 20A. To this end, the phosphor layer 30A may cover the upper surface of the light emitting device 20A. Additionally, the phosphor layer 30a may cover a side surface of the light emitting device 20A. The phosphor layer 30A may have a recessed space RS, which is configured to accommodate the upper electrode 22 of the light emitting device 20A and the bonding wire 60. For example, the phosphor layer 30A may include a body 31a formed to have a substantially uniform thickness t1 on a part of an upper surface of the light emitting device 20A. The phosphor layer 30A may include a side surface cap 32a which is materially continuous with the body 31a. The side surface cap 32a may cover a side surface of the light emitting layer 21L. The phosphor layer 30A may include an upper cap 33a which is materially continuous with the body 31a. The upper cap 33a may be formed to correspond to the upper electrode 22 by being spaced apart by a height H_{R} of the recessed space RS. The height H_{R} of the recessed space RS may be a distance between an upper surface of the light emitting device 20A and a lower surface of the upper cap 33a of the phosphor layer 30A. For example, the upper electrode 22 of the light emitting device 20A may have a negligible thickness. Thus, a distance between the upper electrode 22 of the light emitting device 20A and the upper cap 33a of the phosphor layer 30A may be substantially same as the height H_{R} of the recessed space RS of the phosphor layer 30A. The height H_{R} of the recessed space RS may be smaller than the thickness t1 of the body 31a.

The body 31a may cover the upper surface of the light emitting device 20A except the recessed space RS. A side surface of the body 31a may protrude from the side surface of the light emitting device 20A, or be in contact with the recessed space RS.

The side surface cap 32a may partially cover the side surface of the light emitting device 20A. For example, the side surface cap 32a may be formed to expose the side surface of the light emitting device 20A in contact with the recessed space RS. The side surface cap 32a may be formed from the upper surface of the main body 21 to a lower surface of the light emitting layer 21L. Alternatively, the side surface cap 32a may be formed to have a longer length than a length 1 from the upper surface of the main body 21 to the lower surface of the light emitting layer 21L. A lower surface of the side surface cap 32a may be spaced apart from the package substrate 10. A horizontal width w of the side surface cap 32a may be greater than or equal to t1/4 (w≧t1/4). If the horizontal width w of the side surface cap 32a is less than t1/4, the quality of light may be reduced by an unbalanced thickness of the phosphor layer 30A configured to cover the upper surface and side surface of the light emitting device 20A. Here, t1 is a thickness of the body 31a.

An upper surface of the upper cap 33a may have the same horizontal co-planar plane as an upper surface of the body 31a. A lower surface of the upper cap 33a may be in contact with the recessed space RS. A side surface of the upper cap 33a may protrude from the side surface of the light emitting device 20A, or contact the side surface of the body 31a in contact with the recessed space RS. A thickness t2 of the upper cap 33a may be greater than or equal to t1/4 (t2≧t1/4). If the thickness t2 of the upper cap 33a is less than t1/4, the quality of light may be reduced by an unbalanced thickness of the phosphor layer 30A formed on the upper portion of the light emitting device 20A.

The recessed space RS may include the upper electrode 22 and at least a part of a space (hereinafter, referred to as a bonding space BS) corresponding to the bonding wire 60 bonded to the upper electrode 22 by a wire.

In the embodiment, the height H_{R} of the recessed space RS may be greater than or equal to a height H_{B} of the bonding space BS. Here, the height H_{B} of the bonding space BS may be defined as a sum of a loop height h1 and a tolerance height h2.

Although a height of the upper electrode 22 is exaggerated to make easier understanding of the embodiment of the inventive concept, it can be assumed that the height of the upper electrode 22 may be ignored. Therefore, it is assumed that the loop height h1 means a height from the upper surface of the main body 21 on which the upper electrode 22 is formed to a maximum height of the bonding wire 60.

Meanwhile, the loop height h1 may be changed according to a wire bonding method. The loop height h1 may be a predetermined constant according to the wire bonding method. For example, when the wire bonding is performed as a normal bonding, the loop height h1 may be about 150 μm. When the wire bonding is performed as a reverse bonding, the loop height h1 may be about 80 μm. The tolerance height h2, as a process error according to a process when a phosphor layer is processed, may be a predetermined constant according to the desired light emitting device package design. In the embodiment of the inventive concept, the tolerance height h2 may be about 15 μm to 25 μm.

The phosphor layer 30A may include a base resin and a phosphor. For example, the base resin may include glass. The phosphor may include various phosphors according to light output from the light emitting device 20A. For example, the phosphor may include a yellow phosphor.

The molding unit 40 may be formed to cover the light emitting device 20A and the phosphor layer 30A on the package substrate 10. The molding unit 40 may be formed in a hemispheric shape on the package substrate 10. The molding unit 40 may protect a product including the light emitting device 20A and the phosphor layer 30A, etc. Further, curvature of the hemisphere may be adjusted to form the molding unit 40 so that the intensity of radiation is improved. A directivity angle of light emitted from the light emitting device 20A may be adjusted to improve the intensity of radiation, depending on the curvature. The molding unit 40 may include phenyl-silicon.

The conductive adhesive member 50 may be disposed between the first wiring pattern 11 of the package substrate 10 and a lower electrode 23 of the light emitting device 20A. The conductive adhesive member 50 may electrically connect the first wiring pattern 11 of the package substrate 10 with the lower electrode 23 of the light emitting device 20A. The conductive adhesive member 50 may include a eutectic material. For example, the eutectic material may include one of AuSn, AuGe, and AuSi.

The bonding wire 60 may be connected to the upper electrode 22 of the light emitting device 20A and the second wiring pattern 12 of the package substrate 10. The bonding wire 60 may include gold (Au).

The insulating adhesive member 70 may be disposed between the light emitting device 20A and the phosphor layer 30A. For example, the insulating adhesive member 70 may be disposed between the upper surface of the light emitting device 20A and a lower surface of the body 31a. The insulating adhesive member 70 may include silicon. Although a height of the insulating adhesive member 70 is exaggerated to make easier understanding of the embodiment of the inventive concept, it can be assumed that the height of the insulating adhesive member 70 may be ignored because it is substantially very small.

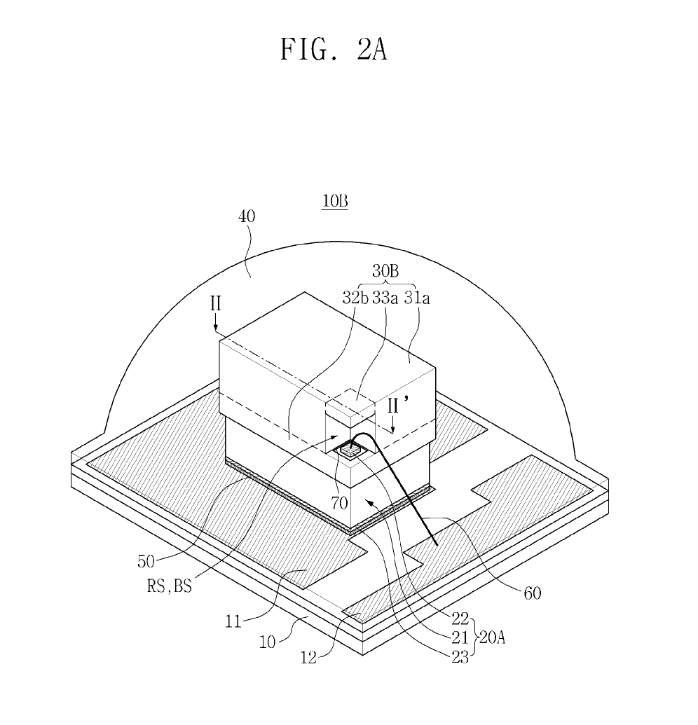

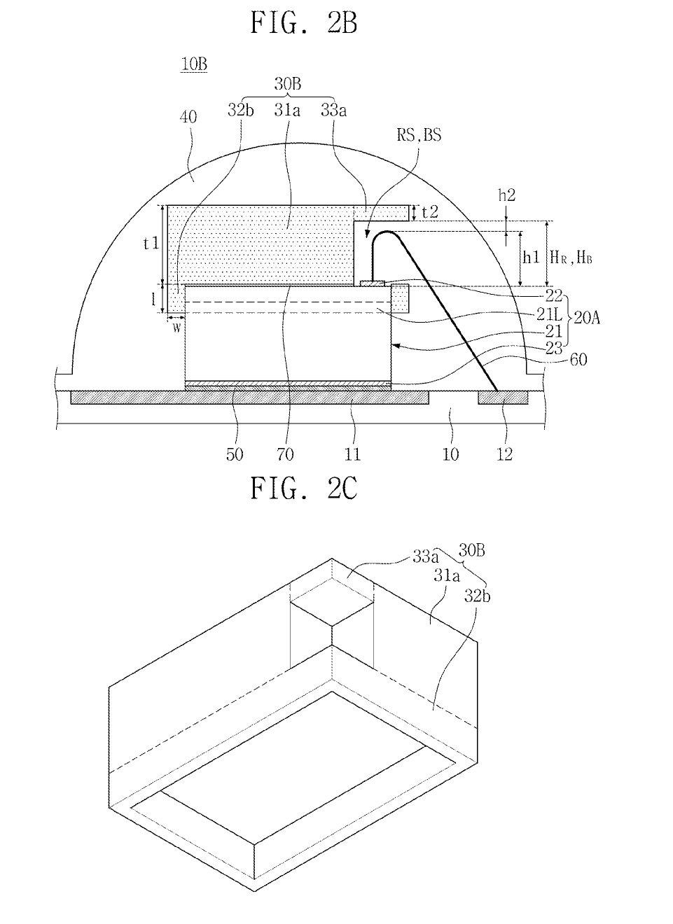

FIG. 2A is a perspective view of a light emitting device package in accordance with an embodiment of the inventive concept, FIG. 2B is a cross-sectional view taken along line II-II′ of FIG. 2A, and FIG. 2C is a bottom perspective view of a phosphor layer shown in FIG. 2A. Because a light emitting device package 10B in accordance with an embodiment is the same as the light emitting device package 10A shown in FIGS. 1A and 1B except a structure of a side surface cap 32b of a phosphor layer 30B, descriptions of the same components have been detailed by the described above.

Referring to FIGS. 2A to 2C, the light emitting device package 10B in accordance with the embodiment of the inventive concept may include a package substrate 10, a light emitting device 20A, and the phosphor layer 30B. The light emitting device package 10B in accordance with the embodiment of the inventive concept may further include a molding unit 40, a conductive adhesive member 50, a bonding wire 60, and an insulating adhesive member 70.

The side surface cap 32b of the phosphor layer 30B may be formed to fully cover a light emitting layer 21L of the light emitting device 20A. For example, the side surface cap 32b may cover all four side surfaces of the light emitting device 20A. The side surface cap 32b may be formed from an upper surface of a main body 21 to a lower surface of the light emitting layer 21L. Alternatively, the side surface cap 32b may be formed to have a longer length than a length 1 from the upper surface of the main body 21 to the lower surface of the light emitting layer 21L. A lower surface of the side surface cap 32b may be spaced apart from the package substrate 10. A horizontal width w of the side surface cap 32b may be greater than or equal to t1/4 (w≧t1/4). If the horizontal width w of the side surface cap 32b is less than t1/4, the quality of light may be reduced by an unbalanced thickness of the phosphor layer 30B configured to cover the upper surface and side surface of the light emitting device 20A. Here, t1 is a thickness of the body 31a.

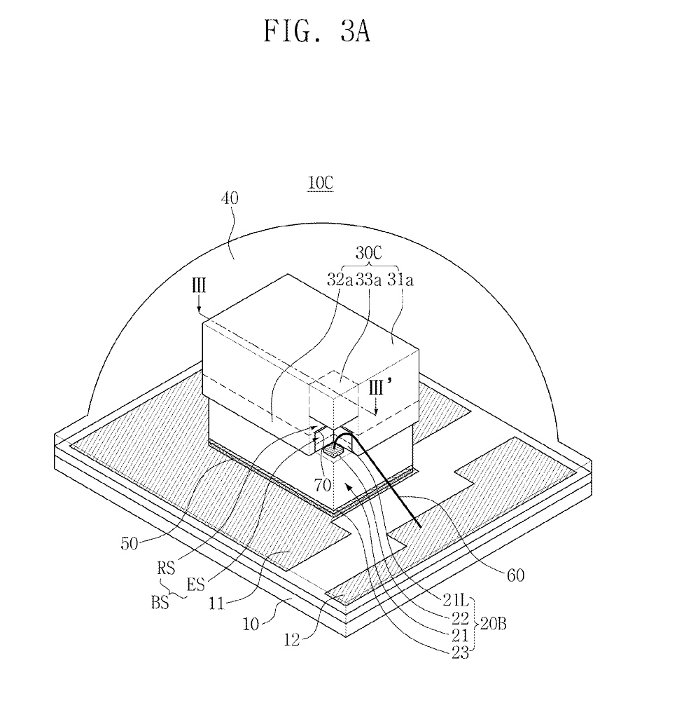

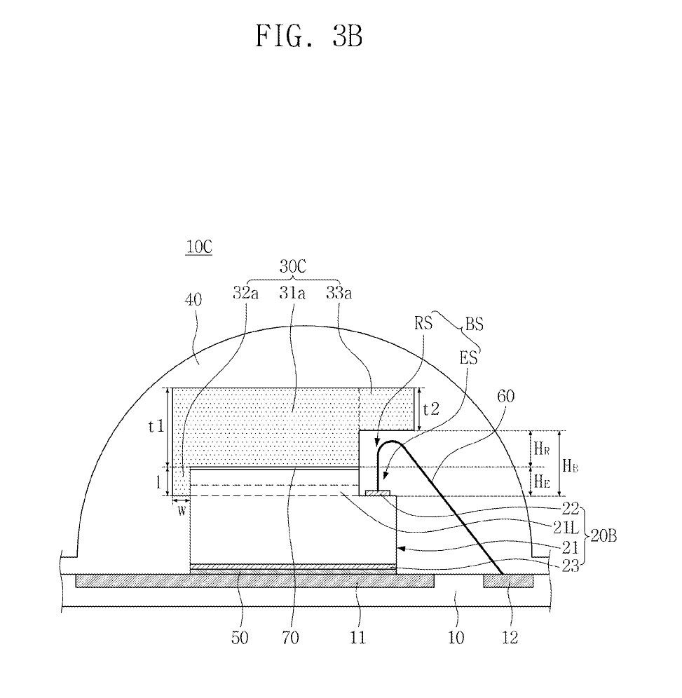

FIG. 3A is a perspective view of a light emitting device package in accordance with an embodiment of the inventive concept, and FIG. 3B is a cross-sectional view taken along line III-III′ of FIG. 3A. Because a light emitting device package 10C in accordance with an embodiment is the same as the light emitting device package 10A shown in FIGS. 1A and 1B except structures of a light emitting device 20B and a phosphor layer 30C, descriptions of the same components have been detailed by the described above.

Referring to FIGS. 3A and 3B, the light emitting device package 10C in accordance with the embodiment of the inventive concept may include a package substrate 10, a light emitting device 20B, and the phosphor layer 30C. The light emitting device package 10C in accordance with the embodiment of the inventive concept may further include a molding unit 40, a conductive adhesive member 50, a bonding wire 60, and an insulating adhesive member 70.

The light emitting device 20B may be mounted on the package substrate 10. For example, the light emitting device 20B may be mounted on a first wiring pattern 11 of the package substrate 10. The light emitting device 20B may include a main body 21 having a light emitting layer 21L therein. The light emitting device 20B may have an etched space ES partially and vertically etched from an upper surface of the main body 21. The etched space ES may be etched to the light emitting layer 21L, or to deeper than the light emitting layer 21L. A part of a side surface of the light emitting layer 21L may be exposed by the etched space ES. For example, a length 1 of the side surface cap 32a of the phosphor layer 30C may be same as height H_{E} of the etched space. The light emitting device 20B may have one or more upper electrodes 22 formed on an upper surface exposed by the etched space ES, and a lower electrode 23 formed on a lower surface of the light emitting device 20B. Although one upper electrode 22 is shown to make easier understanding of the embodiment of the inventive concept, the embodiment of the inventive concept is not limited thereto, and a plurality of upper electrodes 22 can be formed. The light emitting device 20B may include a blue LED to output a blue-light.

Because the phosphor layer 30C is the same as the phosphor layer 30A shown in FIGS. 1A to 1C except a height H_{R} of recessed space RS, detailed descriptions thereof will be omitted.

In the embodiment, the recessed space RS of the phosphor layer 30C may be vertically arranged with the etched space ES of the light emitting device 20B. The recessed space RS of the phosphor layer 30C may be disposed between the etched space ES of the light emitting device 20B and the upper cap 33a of the phosphor layer 30C. The height H_{E} of the etched space ES of the light emitting device 20B may be a distance between an upper surface of the light emitting device 20A and a lower surface of the electrode 22 of the light emitting device 20B. For example, the upper electrode 22 of the light emitting device 20B may have a negligible thickness. That is, a distance between the upper electrode 22 of the light emitting device 20B and the upper cap 33a of the phosphor layer 30C may be substantially same as the sum of the height H_{R} of the recessed space RS of the phosphor layer 30C and the height H_{E} of the etched space ES of the light emitting device 20B. The recessed space RS may include at least a part of a bonding space BS. That is, the height H_{R} of the recessed space RS may be greater than or equal to a difference between a height H_{B} of the bonding space BS and a height H_{E} of the etched space ES. Here, the height H_{E} of the etched space ES may be a predetermined constant according to the selected light emitting device 20B.

Comparing FIGS. 1B and 3B, the heights H_{R} of the recessed spaces RS of the phosphor layers 30A and 30C may be changed depending on presence of the etched spaces ES of the light emitting devices 20A and 20B. The thicknesses t2 of the upper caps 33a may also be changed. For example, in the light emitting device package 10C compared to the light emitting device package 10A, the height H_{R} of the recessed space RS may be as small as the height H_{E} of the etched space ES. Therefore, the thickness t2 of the upper cap 33a of the phosphor layer 30C may be greater than that of the upper cap 33a of the phosphor layer 30A illustrated in FIGS. 1A and 1B. The thickness of t2 of the upper cap 33a of the phosphor layer 30C may be greater than the height H_{E} of the etched space of the light emitting device 20B. For example, the thickness t2 of the upper cap 33a of the phosphor layer 30C may be greater that the horizontal width W of the side surface cap 32a of the phosphor layer 30C.

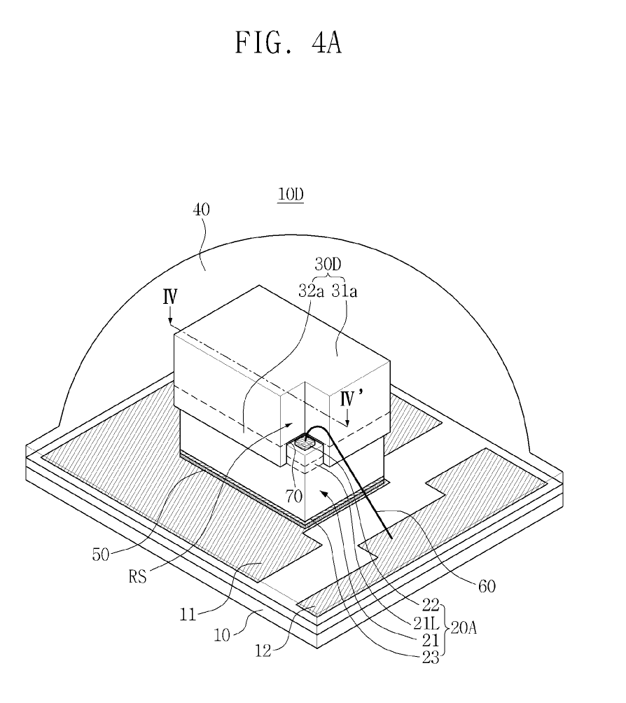

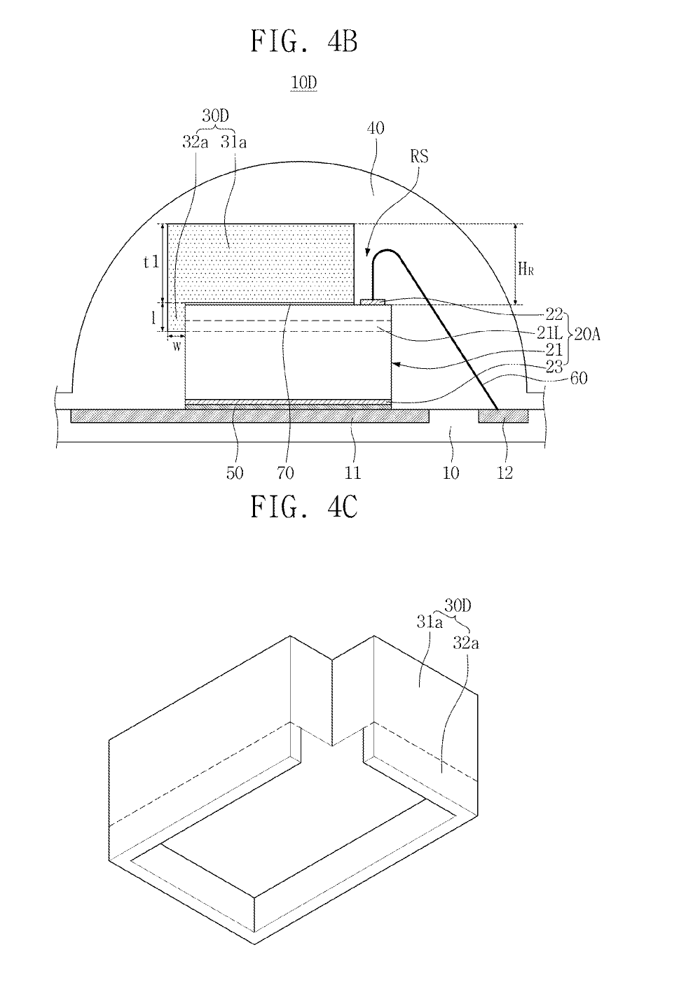

FIG. 4A is a perspective view of a light emitting device package in accordance with an embodiment of the inventive concept, FIG. 4B is a cross-sectional view taken along line IV-IV′ of FIG. 4A, and FIG. 4C is a bottom perspective view of a phosphor layer shown in FIG. 4A. Because a light emitting device package 10D in accordance with an embodiment is the same as the light emitting device package 10A shown in FIGS. 1A and 1B except a structure of a phosphor layer 30D, descriptions of the same components have been detailed by the described above.

Referring to FIGS. 4A to 4C, the light emitting device package 10D in accordance with the embodiment of the inventive concept may include a package substrate 10, a light emitting device 20A, and the phosphor layer 30D. The light emitting device package 10D in accordance with the embodiment of the inventive concept may further include a molding unit 40, a conductive adhesive member 50, a bonding wire 60, and an insulating adhesive member 70.

The phosphor layer 30D may be formed to cover a side surface of the light emitting device 20A on the light emitting device 20A. The phosphor layer 30D may have a recessed space RS configured to accommodate an upper electrode 22 of the light emitting device 20A and the bonding wire 60.

For example, the phosphor layer 30D may include a body 31a formed to have a substantially uniform thickness t1 on a part of an upper surface of the light emitting device 20A. The phosphor layer 30D may include a side surface cap 32a which is materially continuous with the body 31a. The side surface cap 32a may cover a side surface of a light emitting layer 21L. Here, a height H_{R} of the recessed space RS may be the same as the thickness t1 of the body 31a.

The body 31a may cover an upper surface of the light emitting device 20A except the recessed space RS. A side surface of the body 31a may protrude from the side surface of the light emitting device 20A, or be in contact with the recessed space RS.

The side surface cap 32a may partially cover the side surface of the light emitting device 20A. For example, the side surface cap 32a may be formed to expose the side surface of the light emitting device 20A in contact with the recessed space RS. The side surface cap 32a may be formed from an upper surface of a main body 21 to a lower surface of the light emitting layer 21L. Alternatively, the side surface cap 32a may be formed to have a longer length than a length 1 from the upper surface of the main body 21 to the lower surface of the light emitting layer 21L. A lower surface of the side surface cap 32a may be spaced apart from the package substrate 10. A horizontal width w of the side surface cap 32a may be greater than or equal to t1/4 (w≧t1/4). If the horizontal width w of the side surface cap 32a is less than t1/4, the quality of light may be reduced by an unbalanced thickness of the phosphor layer 30D configured to cover the upper and side surfaces of the light emitting device 20A. Here, t1 is a thickness of the body 31a.

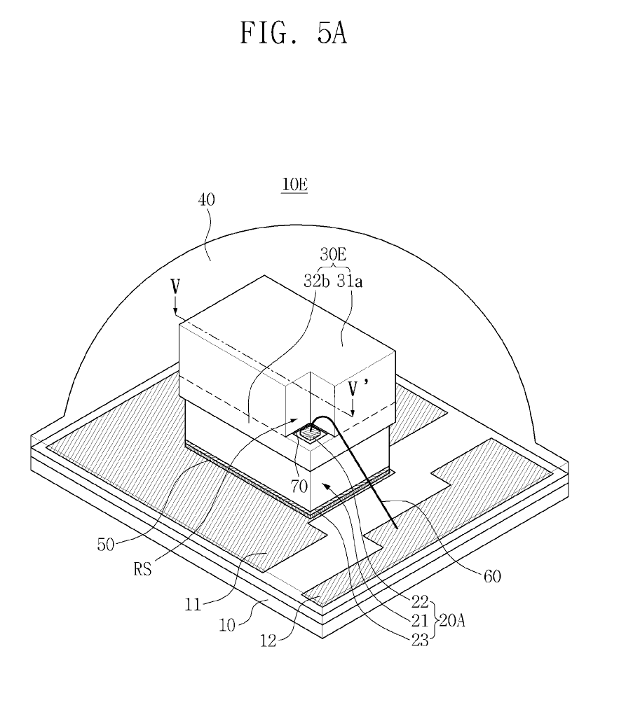

FIG. 5A is a perspective view of a light emitting device package in accordance with an embodiment of the inventive concept, FIG. 5B is a cross-sectional view taken along line V-V′ of FIG. 5A, and FIG. 5C is a bottom perspective view of a phosphor layer shown in FIG. 5A. Because a light emitting device package 10E in accordance with an embodiment is the same as the light emitting device package 10D shown in FIGS. 4A and 4B except a structure of a side surface cap 32b of a phosphor layer 30E formed on a light emitting device 20A, descriptions of the same components have been detailed by the described above.

Referring to FIGS. 5A to 5C, the light emitting device package 10E in accordance with the embodiment of the inventive concept may include a package substrate 10, the light emitting device 20A, and the phosphor layer 30E. The light emitting device package 10E in accordance with the embodiment of the inventive concept may further include a molding unit 40, a conductive adhesive member 50, a bonding wire 60, and an insulating adhesive member 70.

The side surface cap 32b of the phosphor layer 30E may be formed to fully cover a light emitting layer 21L of the light emitting device 20A. For example, the side surface cap 32b may cover all four side surfaces of the light emitting device 20A. The side surface cap 32b may be formed from an upper surface of a main body 21 to a lower surface of the light emitting layer 21L. Alternatively, the side surface cap 32b may be formed to have a longer length than a length 1 from the upper surface of the main body 21 to the lower surface of the light emitting layer 21L. A lower surface of the side surface cap 32b may be spaced apart from the package substrate 10. A horizontal width w of the side surface cap 32b may be greater than or equal to t1/4 (w≧t1/4). If the horizontal width w of the side surface cap 32b is less than t1/4, the quality of light may be reduced by an unbalanced thickness of the phosphor layer 30E configured to cover the upper surface and side surface of the light emitting device 20A. Here, t1 is a thickness of the body 31a.

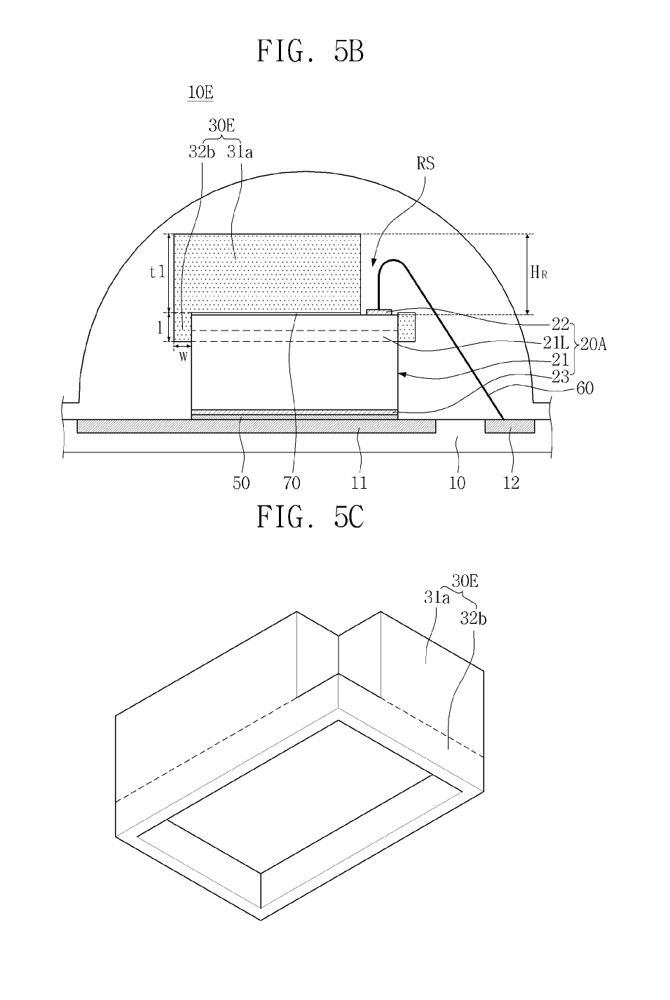

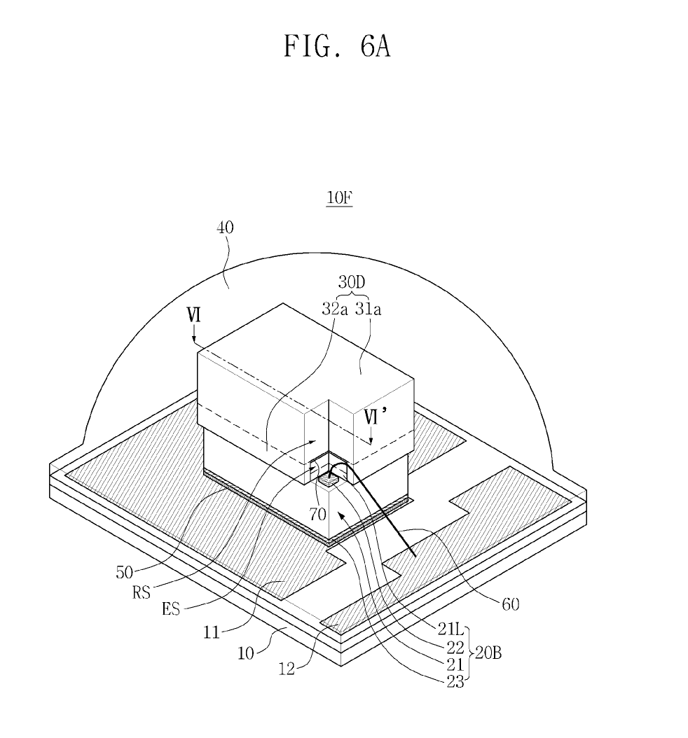

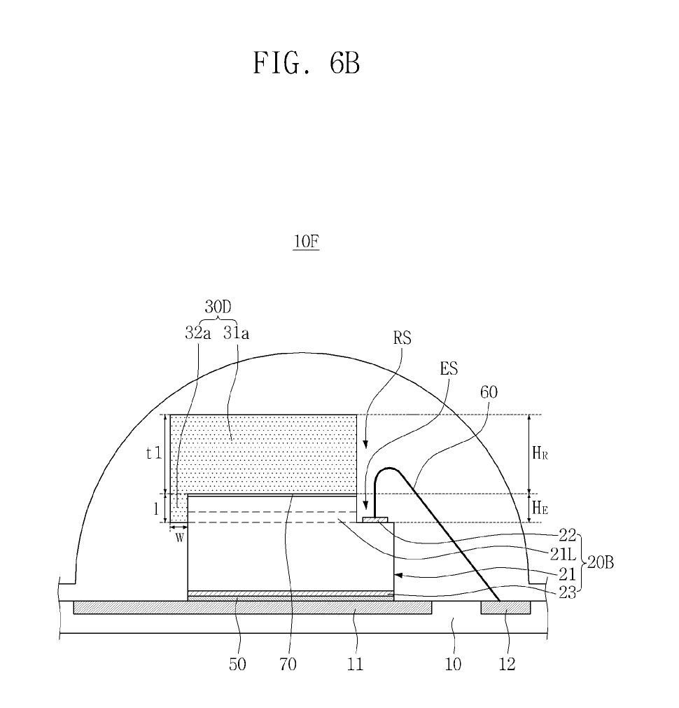

FIG. 6A is a perspective view of a light emitting device package in accordance with an embodiment of the inventive concept, and FIG. 6B is a cross-sectional view taken along line VI-VI′ of FIG. 6A. Because a light emitting device package 10F in accordance with an embodiment is the same as the light emitting device package 10D shown in FIGS. 4A and 4B except structures of a light emitting device 20B, descriptions of the same components have been detailed by the described above.

Referring to FIGS. 6A and 6B, the light emitting device package 10F in accordance with the embodiment of the inventive concept may include a package substrate 10, a light emitting device 20B, and a phosphor layer 30D. The light emitting device package 10F in accordance with the embodiment of the inventive concept may further include a molding unit 40, a conductive adhesive member 50, a bonding wire 60, and an insulating adhesive member 70.

Because the light emitting device 20B is the same as the light emitting device 20B shown in FIGS. 3A and 3B, detailed descriptions thereof will be omitted.

In the embodiment, a recessed space RS of the phosphor layer 30D may be vertically arranged with an etched space ES of the light emitting device 20B. A height H_{R} of the recessed space RS may be the same as a thickness t1 of a body 31a.

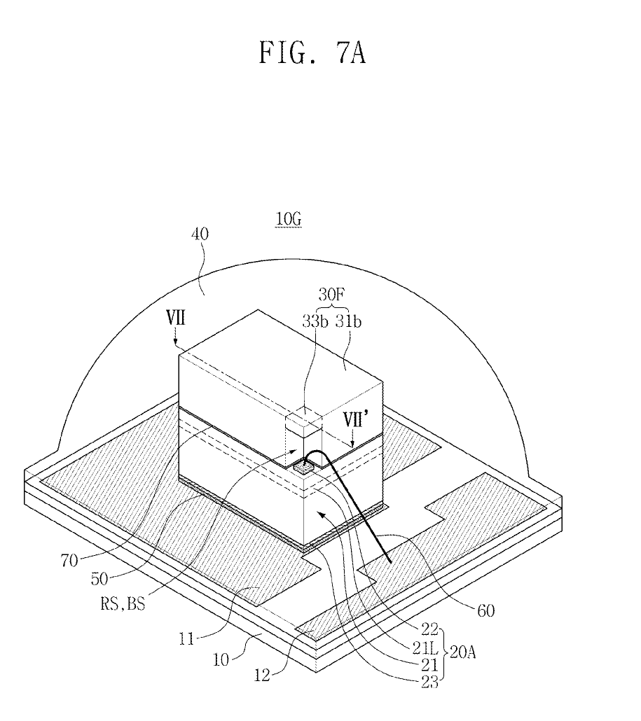

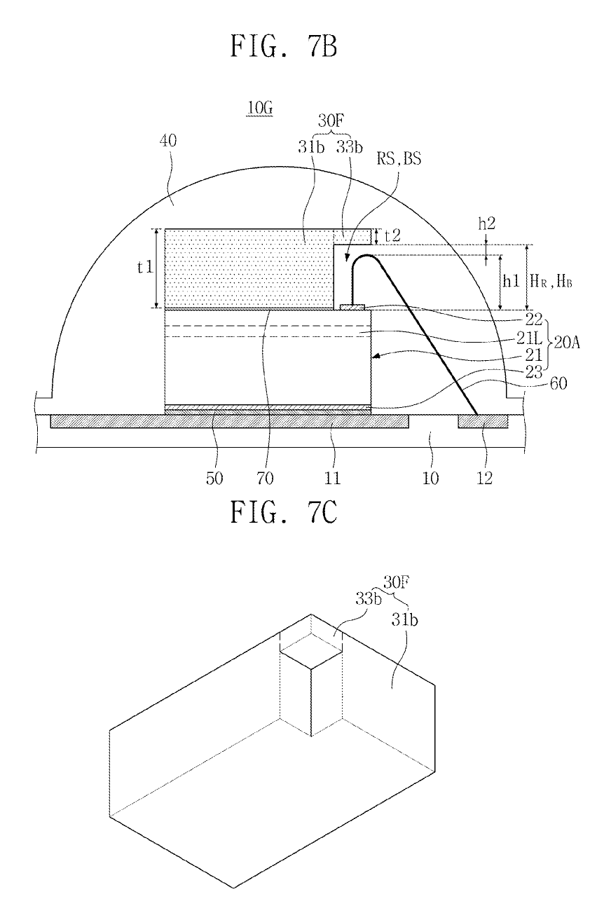

FIG. 7A is a perspective view of a light emitting device package in accordance with an embodiment of the inventive concept, FIG. 7B is a cross-sectional view taken along line VII-VII′ of FIG. 7A, and FIG. 7C is a bottom perspective view of a phosphor layer shown in FIG. 7A. Because a light emitting device package 10G in accordance with an embodiment is the same as the light emitting device package 10A shown in FIGS. 1A and 1B except a structure of a phosphor layer 30F, descriptions of the same components have been detailed by the described above.

Referring to FIGS. 7A to 7C, the light emitting device package 10G in accordance with the embodiment of the inventive concept may include a package substrate 10, a light emitting device 20A, and the phosphor layer 30F. The light emitting device package 10G in accordance with the embodiment of the inventive concept may further include a molding unit 40, a conductive adhesive member 50, a bonding wire 60, and an insulating adhesive member 70.

The phosphor layer 30F may be formed on the light emitting device 20A. The phosphor layer 30F may have a recessed space RS configured to accommodate an upper electrode 22 of the light emitting device 20A, and the bonding wire 60.

For example, the phosphor layer 30F may include a body 31b formed to have a substantially uniform thickness t1 on a part of an upper surface of the light emitting device 20A. The phosphor layer 30F may include an upper cap 33b which is materially continuous with the body 31b. The upper cap 33b may be formed to correspond to the upper electrode 22 by being spaced apart by a height H_{R} of the recessed space RS. The height H_{R} of the recessed space RS may be smaller than the thickness t1 of the body 31b.

The body 31b may cover the upper surface of the light emitting device 20A except the recessed space RS. A side surface of the body 31b may be vertically arranged with a side surface of the light emitting device 20A, or contact the recessed space RS. That is, in the embodiment shown in FIGS. 7A and 7B, the phosphor layer 30F does not include a side surface cap such as the side surface cap 32a of the phosphor layer 30A shown in FIGS. 1A and 1B.

An upper surface of the upper cap 33b may have the same horizontal co-planar plane as an upper surface of the body 31b. A lower surface of the upper cap 33b may be in contact with the recessed space RS. The side surface of the upper cap 33b may be vertically arranged with the side surface of the light emitting device 20A, or contact the side surface of the body 31b in contact with the recessed space RS. A thickness t2 of the upper cap 33b may be greater than or equal to t1/4 (t2≧t1/4). If the thickness t2 of the upper cap 33b is less than t1/4, the quality of light may be reduced by an unbalanced thickness of the phosphor layer 30F formed on the upper portion of the light emitting device 20A. Here, t1 is a thickness of the body 31b.

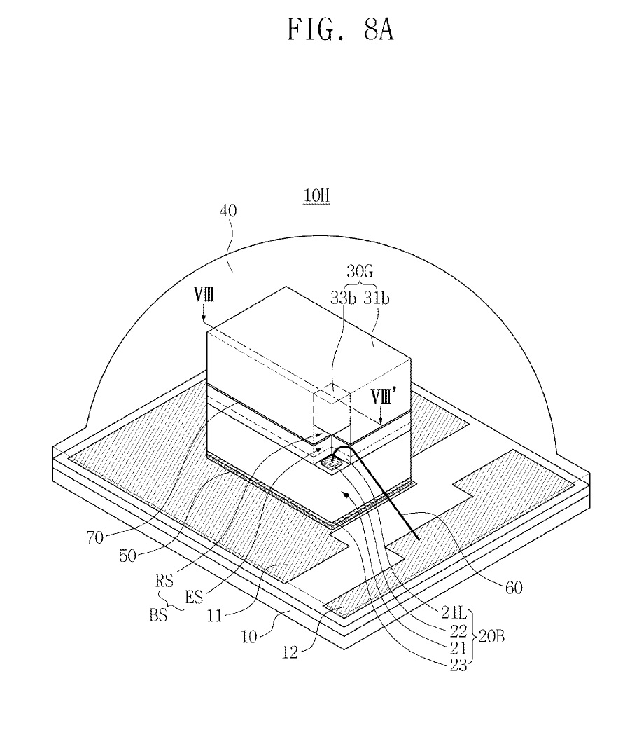

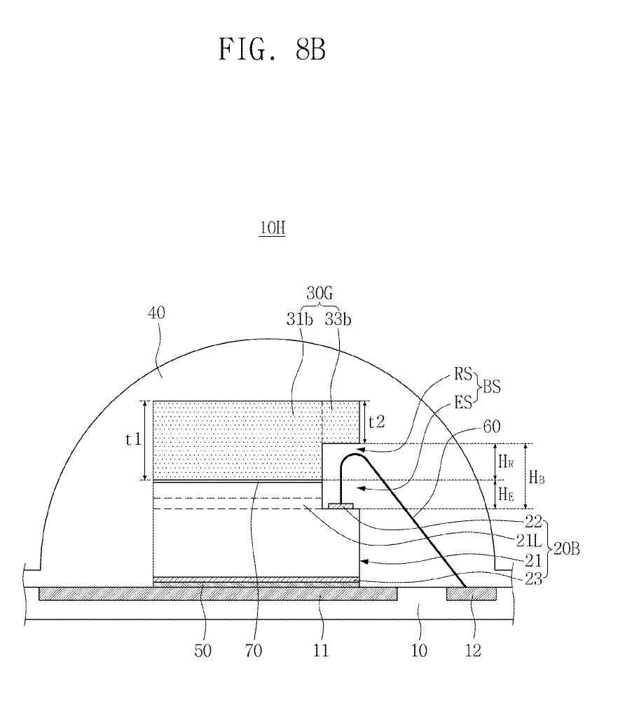

FIG. 8A is a perspective view of a light emitting device package in accordance with an embodiment of the inventive concept, and FIG. 8B is a cross-sectional view taken along line VIII-VIII′ of FIG. 8A. Because a light emitting device package 10H in accordance with an embodiment is the same as the light emitting device package 10G shown in FIGS. 7A and 7B except structures of a light emitting device 20B and a phosphor layer 30G, descriptions of the same components have been detailed by the described above.

Referring to FIGS. 8A and 8B, the light emitting device package 10H in accordance with the embodiment of the inventive concept may include a package substrate 10, a light emitting device 20B, and the phosphor layer 30G. The light emitting device package 10H in accordance with the embodiment of the inventive concept may further include a molding unit 40, a conductive adhesive member 50, a bonding wire 60, and an insulating adhesive member 70.

Because the light emitting device 20B is the same as the light emitting device 20B shown in FIGS. 3A and 3B, detailed descriptions thereof will be omitted. Because the phosphor layer 30G is the same as the phosphor layer 30F shown in FIGS. 7A and 7B except a height H_{R} of recessed space RS, detailed descriptions thereof will be omitted.

In the embodiment, the recessed space RS of the phosphor layer 30G may be vertically arranged with the etched space ES of the light emitting device 20B. The recessed space RS may include at least a part of a bonding space BS. That is, a height H_{R} of the recessed space RS may be greater than or equal to a difference between a height H_{B} of the bonding space BS and a height H_{E} of the etched space ES. Here, the height H_{E} of the etched space ES may be a predetermined constant according to the selected light emitting device 20B.

In comparison with FIGS. 7B and 8B, the heights H_{R} of the recessed spaces RS of the phosphor layers 30F and 30G may be changed depending on presence of the etched spaces ES of the light emitting devices 20A and 20B. The thicknesses t2 of the upper caps 33b may also be changed. For example, in the light emitting device package 10H compared to the light emitting device package 10G, the height H_{R} of the recessed space RS may be as small as the height H_{E} of the etched space ES. Therefore, the thickness t2 of the upper cap 33b of the phosphor layer 30G may be greater than that of the upper cap 33b of the phosphor layer 30F.

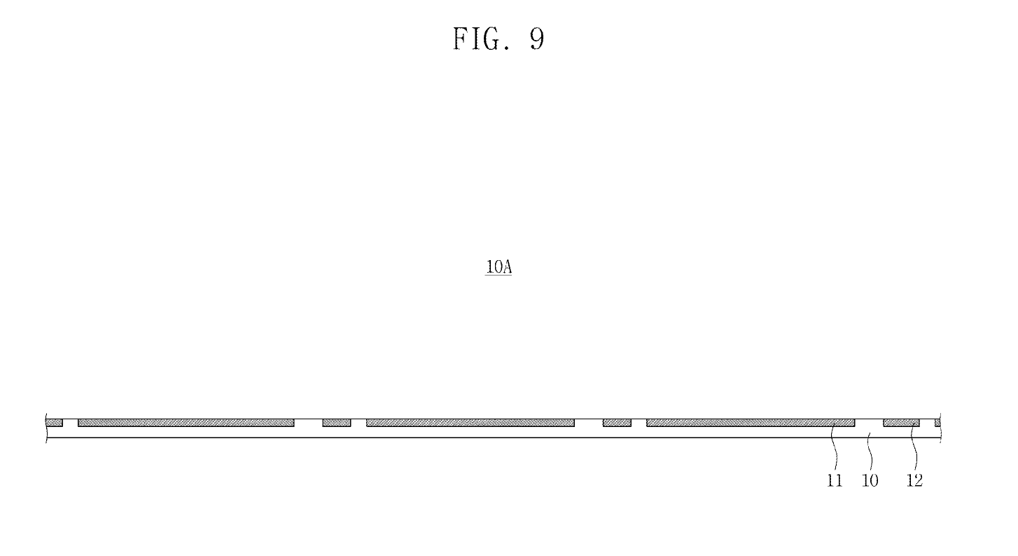

FIGS. 9 to 18 are views showing a method of fabricating a light emitting device package in accordance with embodiments of the inventive concept.

Referring to FIG. 9, the method may include preparing a package substrate 10 including a plurality of first and second wiring patterns 11 and 12. The package substrate 10 may include a ceramic substrate. The plurality of first and second wiring patterns 11 and 12 may include gilding.

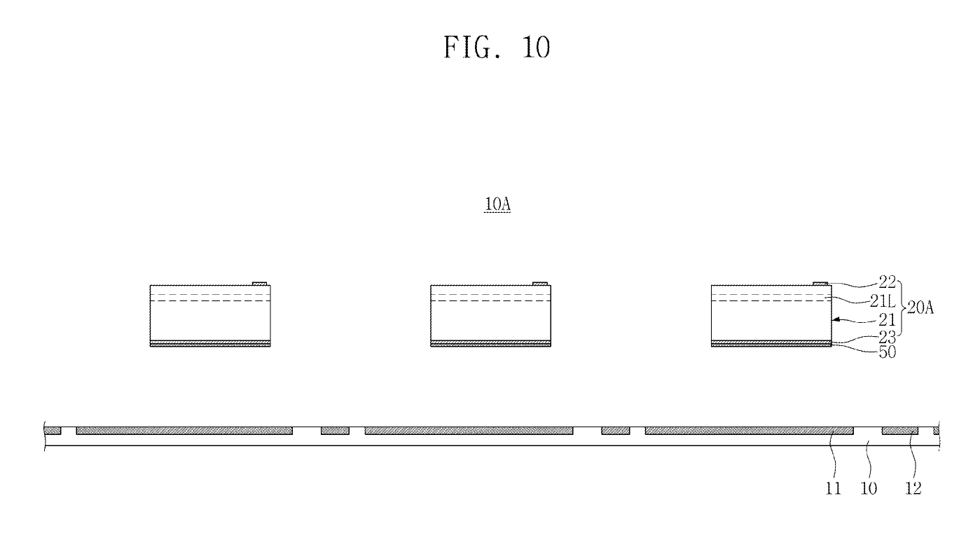

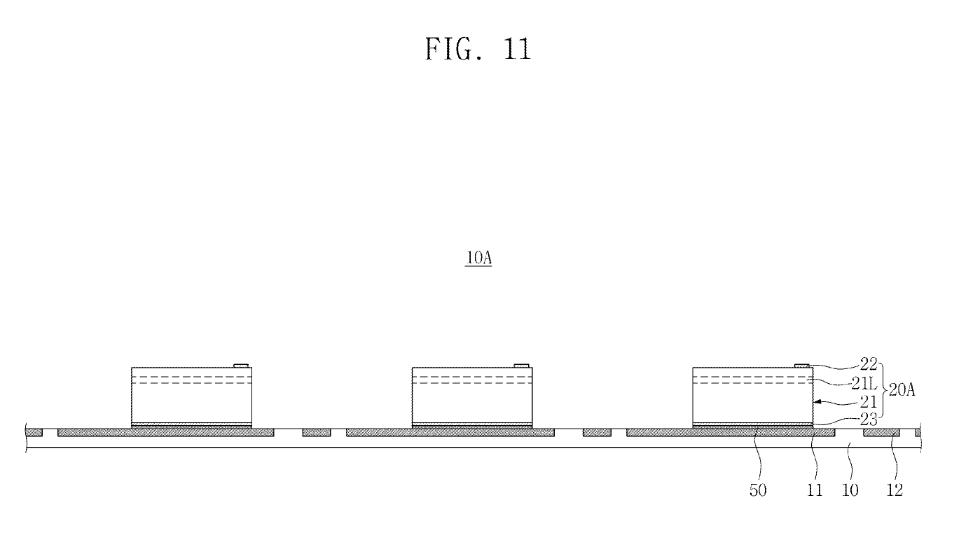

Referring to FIGS. 10 and 11, the method may include mounting a plurality of light emitting devices 20A on the plurality of first wiring patterns 11, respectively, by performing a eutectic bonding process.

Mounting the plurality of light emitting devices 20A on the plurality of first wiring patterns 11, respectively, may include performing the eutectic bonding process on each first wiring pattern 11 and the corresponding light emitting devices 20A through a conductive adhesive member 50 provided between each first wiring pattern 11 and the corresponding light emitting device 20A by heating and vibrating the package substrate 10.

In this process, the package substrate 10 may be heated to about 300° C. The conductive adhesive member 50 may be applied in advance on a lower surface of a lower electrode 23 of the light emitting device 20A. Alternatively, the conductive adhesive member 50 may be stamped on each first wiring pattern 11. The lower electrode 23 of each light emitting device 20A may be connected to the corresponding first wiring pattern 11 through the conductive adhesive member 50. The conductive adhesive member 50 may include one of AuSn, AuGe, and AuSi.

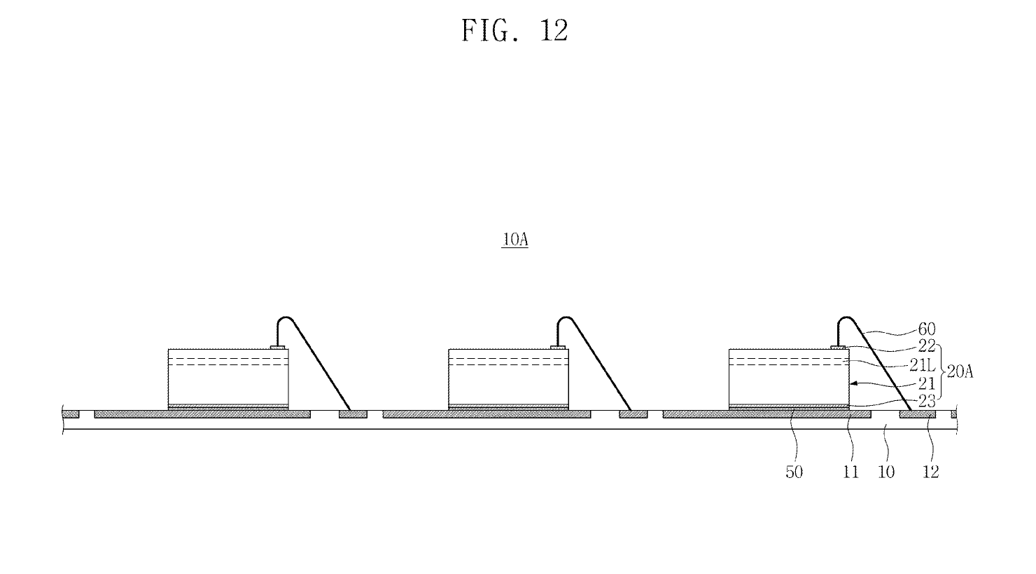

Referring to FIG. 12, the method may include performing a wire bonding on an upper electrode 22 formed on an upper surface of the light emitting device 20A, and a second wiring pattern 12 by using a bonding wire 60. The upper electrode 22 of the light emitting device 20A may be connected to the corresponding second wiring pattern 12 through the bonding wire 60. The bonding wire 60 may include gold (Au).

Referring to FIG. 13, the method may include providing an insulating adhesive member 70 on the upper surface of the light emitting device 20A by performing a stamping process. The insulating adhesive member 70 may include silicon.

Referring to FIG. 14, the method may include stacking a phosphor layer 30A on the insulating adhesive member 70 and applying pressure thereto, and heating and curing the insulating adhesive member 70.

When the phosphor layer 30A is stacked on the insulating adhesive member 70, and the pressure is applied thereto, the insulating adhesive member 70 may spread to contact a lower surface of a body 31a of the phosphor layer 30A. The insulating adhesive member 70 may be heated at about 150° C. for about 1 to 2 hours. The insulating adhesive member 70 may include silicon.

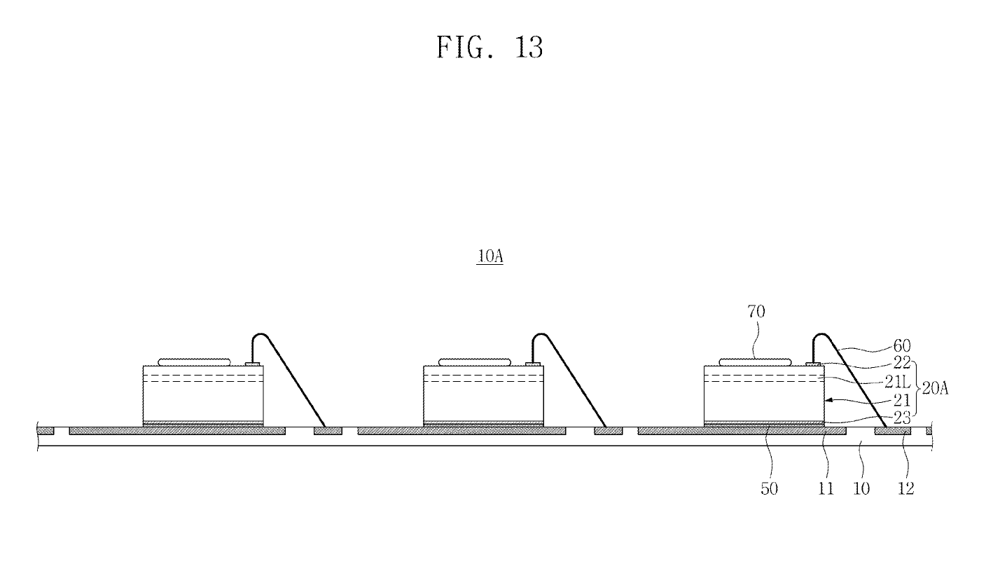

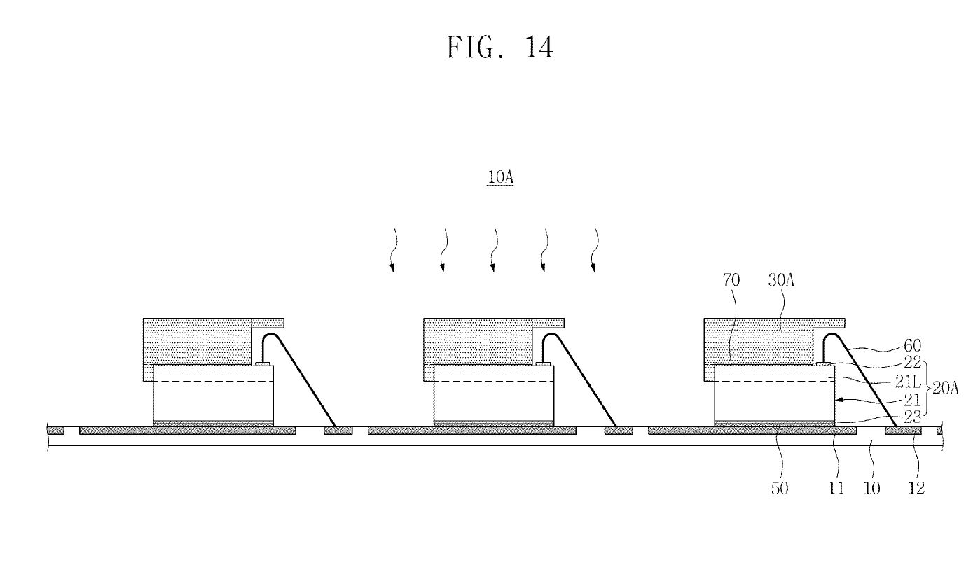

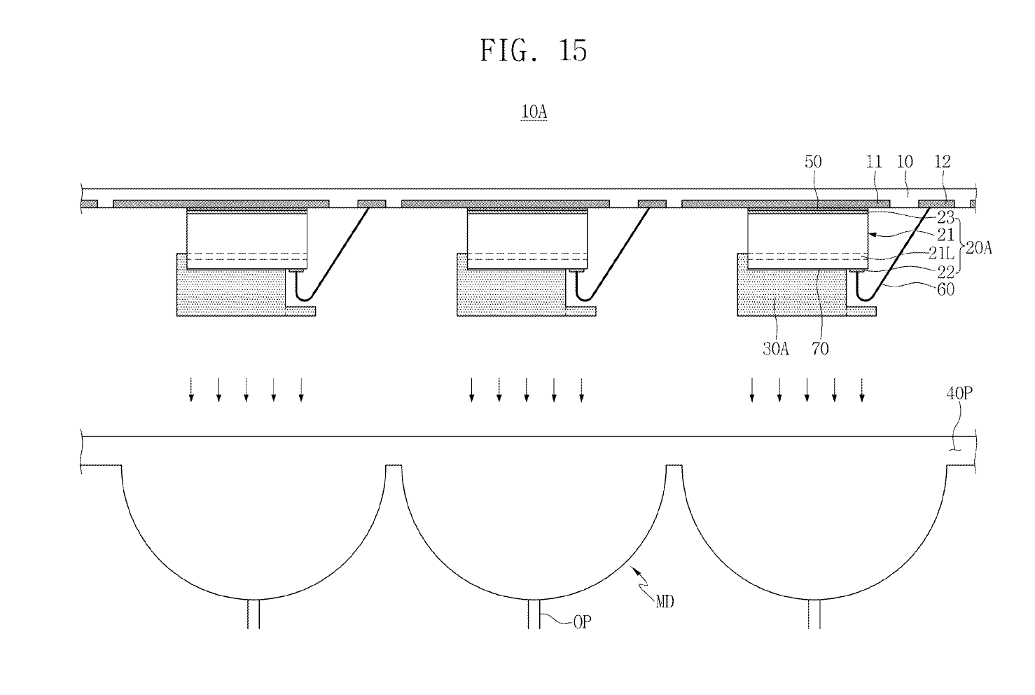

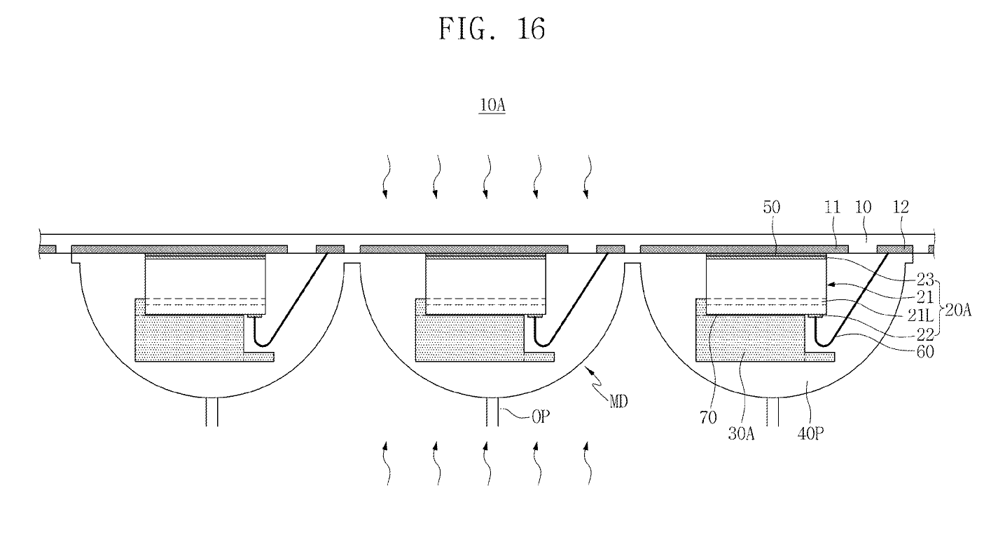

Referring to FIGS. 15 and 16, the method may include forming a molding unit 40 to cover the light emitting device 20A and the phosphor layer 30A on the package substrate 10.

Forming the molding unit 40 may include filling a molding material 40p in a mold MD, applying pressure to the light emitting device 20A and the phosphor layer 30A to input into the molding material 40p after inverting the package substrate 10, and heating and curing the molding material 40p.

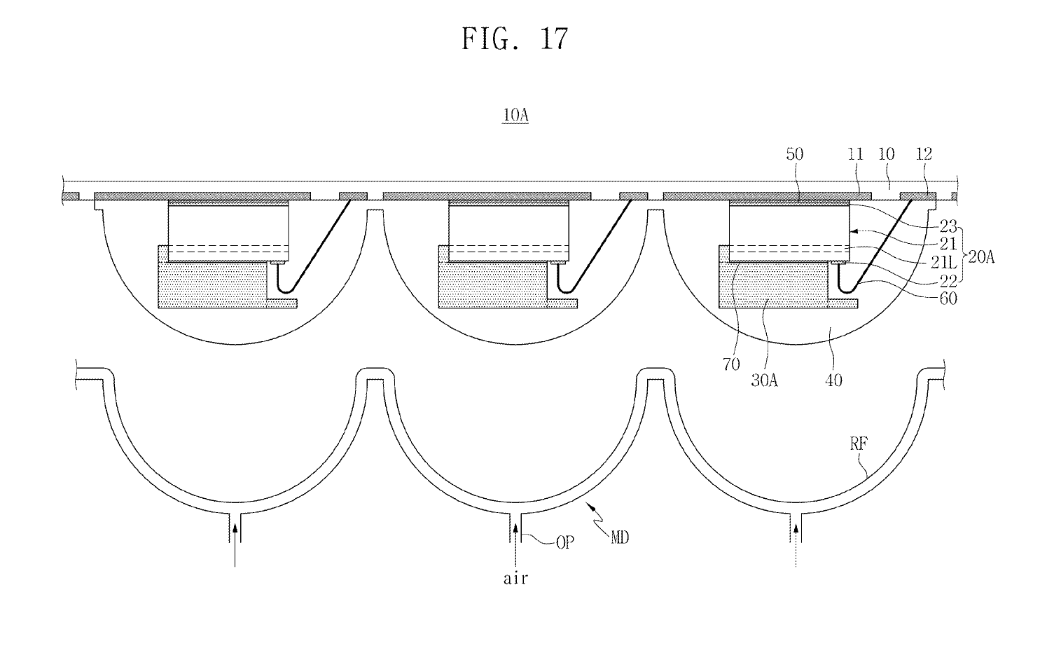

The method may further include disposing a release film RF (see FIG. 17) between the mold MD and the molding material 40p before filling the molding material 40p in the mold MD. Disposing the release film RF may include disposing the release film RF on an inner wall of the mold MD, and performing vacuum suctioning on the air through an injection port OP of the mold MD. The release film RF may be pressed on the inner wall of the mold MD through the vacuum suctioning.

The molding material 40p may be heated at about 180° C. for about 3 to 4 hours. In this process, the molding material 40p may be cured and transformed to the molding unit 40. The molding unit 40 may include phenyl-silicon. A form of the molding unit 40 may be changed according to a form of the mold MD.

Referring to FIG. 17, the method may include separating the molding unit 40 from the mold MD.

Separating the molding unit 40 from the mold MD may include injecting the air through the injection port OP of the mold MD. As the mold MD and the release film RF are separated from each other through the injecting of the air, the molding unit 40 may be easily separated from the mold MD.

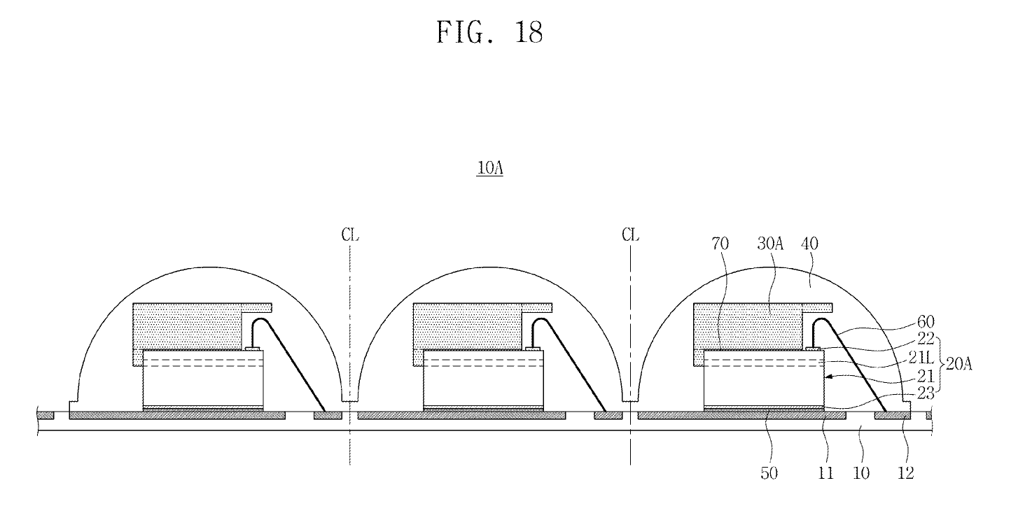

Referring to FIG. 18, the method may include separating a plurality of light emitting device packages 10A into single light emitting device packages 10A along a line CL by performing a sawing or scribing process. Hereby, the light emitting device packages 10A shown in FIGS. 1A and 1B may be formed.

The light emitting device packages 10B to 10H shown in FIGS. 2A to 8B may be completed using the same methods as described above in FIGS. 9 to 18.

As described above, the light emitting device package 10A to 10H in accordance with the embodiments of the inventive concept may provide the phosphor layers 30A to 30G including at least one of the side surface caps 32a and 32b to cover the side surfaces of the light emitting devices 20A and 20B, and the upper caps 33a and 33b formed to correspond to the upper electrodes by being spaced apart from the upper electrodes 22 of the light emitting devices 20A and 20B. Most of the light output from the light emitting devices 20A and 20B may be output through the phosphor layers 30A to 30G including at least one of the side surface caps 32a and 32b, and the upper caps 33a and 33b. A tilt phenomenon of the phosphor layers 30A to 30F caused by surface tension of the insulating adhesive member 70 disposed between the light emitting devices 20A and 20B and the phosphor layers 30A to 30F may be prevented in advance by the side surface caps 32a and 32b. Therefore, since a design with a desired light color is implemented to be uniform, the quality of light may be improved.

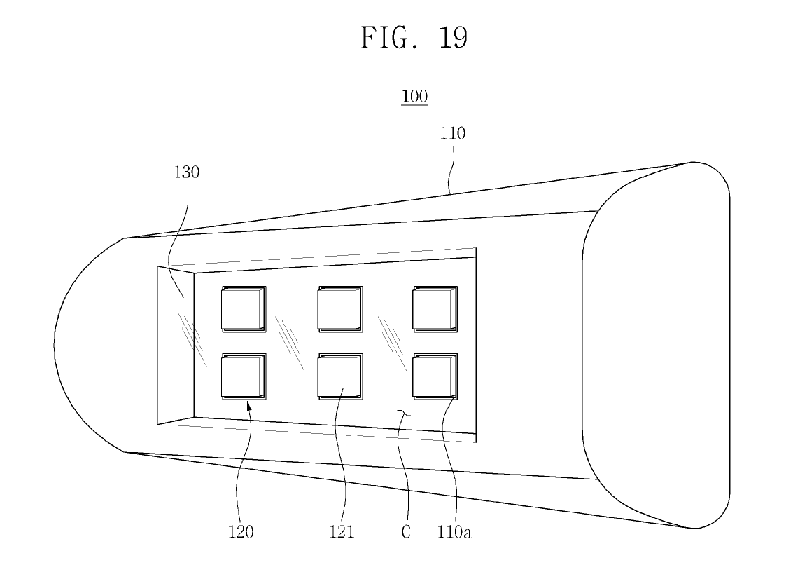

FIG. 19 is a conceptual view illustrating a turn signal lamp 100 including at least one of light emitting device packages 10A to 10H in accordance with various embodiments of the inventive concept. Referring to FIG. 19, a turn signal lamp 100 in accordance with an embodiment of the inventive concept may include a case 110, a light emitting module 120, and a transparent cover 130.

The case 110 may have a light emitting module receiving groove C formed to accommodate the light emitting module 120 in a cavity form. A plurality of opening parts 110a may be formed in a bottom of the light emitting module receiving groove C. The light emitting module 120 may be installed on the light emitting module receiving groove C.

The light emitting module 120 may include the plurality of light emitting device packages 121 disposed on a module substrate (not shown). The module substrate may be installed behind the bottom of the light emitting module receiving groove C, and only expose the plurality of light emitting device packages 121 through the plurality of opening parts 110a. The light emitting device package 121 may include any one of the light emitting device packages 10A to 10H shown in FIGS. 1A to 8B.

The transparent cover 130 may be attached to cover the light emitting module receiving groove C to one surface of the case 110.

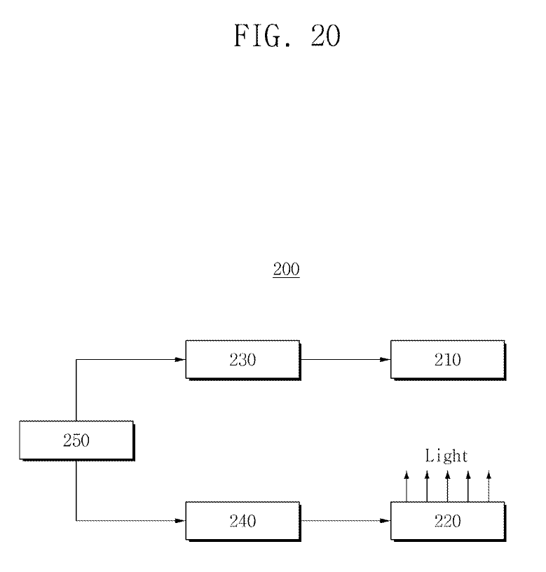

FIG. 20 is a schematic view illustrating a device assembly including at least one of light emitting device packages in accordance with embodiments of the inventive concept. Referring to FIG. 20, a device assembly 200 in accordance with the embodiment of the inventive concept may include a liquid crystal panel 210 to display an image. The device assembly 200 may include a backlight unit 220 to supply a light to the liquid crystal panel 210. The device assembly 200 may include a control circuit unit 230 to supply a control signal, a gate signal, and a data signal to the liquid crystal panel 210. The device assembly 200 may include an inverter circuit unit 240 to control power supply of the backlight unit 220. The device assembly 200 may include a system circuit unit 250 to control the control circuit unit 230 and the inverter circuit unit 240. The device assembly 200 may be a display device assembly.

The liquid crystal panel 210 may include a plurality of pixels, and display an image using the gate signal and the data signal.

The backlight unit 220 may supply a light to the liquid crystal panel 210. The backlight unit 220 may include a light emitting module having a plurality of light emitting device packages disposed on a module substrate. The plurality of light emitting device packages may include any one of the light emitting device packages 10A to 10H shown in FIGS. 1A to 8B.

The control circuit unit 230 may be configured in a printed circuit board (PCB) including a timing controller, a driving integrated circuit, etc. The control circuit unit 230 may supply a plurality of control signals and a RGB signal for displaying an image to the liquid crystal panel 210. Further, the control circuit unit 230 supplies an original or a modulated dimming signal for controlling a backlight unit received from the system circuit unit 250 to the inverter circuit unit 240.

The inverter circuit unit 240 controls light emitting of the backlight unit 220 using the dimming signal received from the control circuit unit 230.

The system circuit unit 250 is an external interface circuit such as a TV system, a graphic card, etc. The system circuit unit 250 supplies an image signal and a plurality of driving signals to the control circuit unit 230. Further, the system circuit unit 250 supplies the dimming signal to the control circuit unit 230.

In accordance with embodiments of the inventive concept, a phosphor layer having a side surface cap and/or an upper cap is provided. The side surface cap can cover a side surface of a light emitting device. The upper cap may be formed to correspond to an upper electrode by being spaced apart from the upper electrode of the light emitting device. Light output from the light emitting device through the side surface cap and/or the upper cap may be output through the phosphor layer. Further, a tilt phenomenon of the phosphor layer by surface tension of an adhesive member disposed between the light emitting device and the phosphor layer can be prevented in advance by the side surface cap. Therefore, since a design with a desired light color is implemented to be uniform, the quality of light can be improved.

The foregoing is illustrative of embodiments and is not to be construed as limiting thereof. Although a few embodiments have been described, those skilled in the art will readily appreciate that many modifications are possible in embodiments without materially departing from the novel teachings and advantages. Accordingly, all such modifications are intended to be included within the scope of this inventive concept as defined in the claims. In the claims, means-plus-function clauses are intended to cover the structures described herein as performing the recited function, and not only structural equivalents but also equivalent structures. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A light emitting device package comprising:
a package substrate having a wiring pattern;
a light emitting device mounted on the package substrate, and having a main body having a light emitting layer therein, and an upper electrode on an upper surface of the main body;
a bonding wire connected to the upper electrode and the wiring pattern; and
a phosphor layer formed on the light emitting device,
wherein the phosphor layer has a recessed space to accommodate the upper electrode and the bonding wire, and the phosphor layer covers a side surface of the light emitting device.

2. The package according to claim 1, wherein the phosphor layer includes:
a phosphor body formed to have a uniform thickness on a part of an upper surface of the light emitting device;
a side surface cap configured to materially continue with the phosphor body, and cover the side surface of the light emitting layer; and
an upper cap configured to materially continue with the phosphor body, and vertically arranged with the upper electrode and spaced apart from the upper electrode,
wherein the height of the recessed space is smaller than the thickness of the phosphor body.

3. The package according to claim 2, wherein a distance between the upper electrode of the light emitting device and the upper cap of the phosphor layer is substantially same as the height of the recessed space.

4. The package according to claim 2, wherein a side surface of the phosphor body protrudes from the side surface of the light emitting device, or contacts the recessed space.

5. The package according to claim 4, wherein a side surface of the upper cap protrudes from the side surface of the light emitting device, or contacts the side surface of the phosphor body in contact with the recessed space.

6. The package according to claim 2, wherein the side surface cap is formed from the upper surface of the main body to a lower surface of the light emitting layer.

7. The package according to claim 2, wherein the side surface cap is formed to expose the side surface of the light emitting device in contact with the recessed space.

8. The package according to claim 2, wherein the recessed space includes at least a part of a bonding space corresponding to the upper electrode and the bonding wire.

9. The package according to claim 8, wherein the height of the recessed space is equal to or greater than a height of the bonding space.

10. The package according to claim 8, wherein the light emitting device has an etched space vertically and partially etched from the upper surface of the main body, and has the upper electrode on an upper surface exposed by the etched space.

11. The package according to claim 10, wherein the recessed space is vertically arranged with the etched space, and the height of the recessed space is equal to or greater than a difference between the height of the bonding space and a height of the etched space.

12. The package according to claim 1, wherein the phosphor layer includes:
a phosphor body formed to have a uniform thickness on a part of an upper surface of the light emitting device; and
a side surface cap configured to materially continue with the body, and cover the side surface of the light emitting layer,
wherein the height of the recessed space is the same as the thickness of the phosphor body.

13. A light emitting device package comprising:
a package substrate having first and second wiring patterns;
a light emitting device mounted on the first wiring pattern, and having an upper electrode;
a bonding wire connected to the upper electrode and the second wiring pattern; and
a phosphor layer formed on the light emitting device,
wherein the phosphor layer has a recessed space to accommodate the upper electrode and the bonding wire.

14. The package according to claim 13, wherein the phosphor layer includes:
a phosphor body formed to have a uniform thickness on a part of an upper surface of the light emitting device; and
an upper cap configured to materially continue with the phosphor body, and formed to vertically arranged with the upper electrode and spaced apart from the upper electrode by a height of the recessed space,
wherein the height of the recessed space is smaller than the thickness of the body.

15. The package according to claim 14, wherein a side surface of the phosphor body is vertically arranged with a side surface of the light emitting device, or contacts the recessed space.

16. The package according to claim 14, wherein a side surface of the upper cap is vertically arranged with the side surface of the light emitting device, or contacts the side surface of the phosphor body in contact with the recessed space.

17. The package according to claim 13, wherein the light emitting device includes a main body having an etched space, the upper electrode being formed on an upper surface of the main body exposed by the etched space,
wherein the recessed space of the phosphor layer is vertically arranged with the etched space of the light emitting device.

18. The package according to claim 17, wherein the main body of the light emitting device further has a light emitting layer, a part of a side surface of the light emitting layer of the main body being exposed by the etched space of the main body.

19. The package according to claim 17, wherein the phosphor layer includes a phosphor body covering an upper surface of the light emitting device except the recessed space, and a side surface cap covering a side surface of the light emitting layer, and
wherein the length of the side surface cap of the phosphor layer is same as the height of the etched space of the light emitting layer.

20. The package according to claim 17, wherein the phosphor layer includes an upper cap vertically arranged with the upper electrode of the light emitting device, and
wherein a distance between the upper electrode of the light emitting device and the upper cap of the phosphor layer is substantially same as the sum of the height of the recessed space of the phosphor layer and the height of the etched space of the light emitting device.
